(19) United States
(12) Patent Application Publication
(10) Pub. No.: US 2020/0035657 A1
(43) Pub. Date: Jan. 30, 2020

(54) ELECTROLUMINESCENT DEVICE AND METHOD OF MANUFACTURING THE SAME

(71) Applicants: BEIJING BOE DISPLAY TECHNOLOGY CO., LTD., Beijing (CN); BOE TECHNOLOGY GROUP CO., LTD., Beijing (CN)

(72) Inventors: Lianjie QU, Beijing (CN); Ruiyong WANG, Beijing (CN); Yun QIU, Beijing (CN); Hebin ZHAO, Beijing (CN); Yonglian QI, Beijing (CN); Bingqiang GUI, Beijing (CN); Hui ZHANG, Beijing (CN)

(21) Appl. No.: 16/397,626

(22) Filed: Apr. 29, 2019

(30) Foreign Application Priority Data
Jul. 27, 2018 (CN) 201810846120.1

(51) Int. Cl. H01L 25/16; H01L 25/075; H01L 23/538; H01L 33/58; H01L 33/62

(52) U.S. Cl. CPC H01L 25/167; H01L 25/0753; H01L 25/165; H01L 23/5387; H01L 2933/0066; H01L 33/62; H01L 2933/0091; H01L 2933/0058; H01L 33/58

(57) ABSTRACT

An electroluminescent device and a manufacturing method thereof are provided. The electroluminescent device includes a transparent substrate and array of electroluminescent chips located thereon, wherein light-emitting surfaces of the electroluminescent chips are attached to the transparent substrate.

### CROSS-REFERENCE TO RELATED APPLICATION

This application claims the priority of Chinese Patent Application No.201810846120.1, filed on Jul. 27, 2018, the contents of which are herein incorporated by reference in their entirety.

### BACKGROUND

The present disclosure relates to the technical field of display, in particular to an electroluminescent device and method of manufacturing the same.

Light-Emitting Diodes (LEDs) array is mainly applied to display or used as a light source. For the LED display array, on one hand, there is a need for down-scaling of the LEDs, and on the other hand, pitch between LEDs is required to be smaller, ranging from millimeter scale to micrometer scale.

### SUMMARY

According to one aspect of the present disclosure, there is provided an electroluminescent device, including a transparent substrate and array of electroluminescent chips located on the transparent substrate, wherein light-emitting surfaces of the electroluminescent chips are attached to the transparent substrate.

In some embodiments, the electroluminescent device may further include a light uniformizing structure attached to a side of the transparent substrate away from the electroluminescent chips, wherein an orthographic projection area of the light uniformizing structure on the transparent substrate at least covers the electroluminescent chips.

In some embodiments, a thickness of the transparent substrate is equal to a light uniformizing distance required by the electroluminescent chips.

In some embodiments, the electroluminescent device may further include a transmittance enhancement layer between the transparent substrate and the electroluminescent chips, and the light-emitting surfaces of the electroluminescent chips are attached to the transmittance enhancement layer, and the transmittance enhancement layer is attached to the transparent substrate.

In some embodiments, the electroluminescent device may further include a confinement layer on a side of the transparent substrate which the electroluminescent chips are attached to, and surrounding the electroluminescent chips.

In some embodiments, a material of the confinement layer may include an organic material, and a thickness of the confinement layer and a thickness of the electroluminescent chips are at the same scale.

In some embodiments, the electroluminescent device may further include a planarization layer covering the confinement layer and the electroluminescent chips; an insulating layer covering the planarization layer; and a drive circuit on the insulating layer, wherein the planarization layer exposes electrodes of the electroluminescent chips, and the drive circuit is electrically connected with the exposed electrodes of the electroluminescent chips through vias penetrating through the insulating layer.

In some embodiments, the electroluminescent device may further include a package layer covering the electroluminescent chips; an insulating layer covering the package layer; and a drive circuit on the insulating layer, wherein the package layer exposes electrodes of the electroluminescent chips, and the drive circuit is electrically connected with the exposed electrode of the electroluminescent chips through vias penetrating through the insulating layer.

According to another aspect of the present disclosure, there is provided a method of manufacturing an electroluminescent device, including providing a transparent substrate; and attaching electroluminescent chips to the transparent substrate, wherein light-emitting surfaces of the electroluminescent chips are attached to the transparent substrate.

In some embodiments, before attaching the electroluminescent chips to the transparent substrate, the method may further include forming a confinement layer on the transparent substrate wherein the confinement layer surrounds positions of the electroluminescent chips to be attached, and after attaching the electroluminescent chips to the transparent substrate, the method may further include forming a planarization layer on the confinement layer and the electroluminescent chips; grinding the planarization layer until electrodes of the electroluminescent chips are exposed; forming an insulating layer on the grinded planarization layer; and forming a drive circuit on the insulating layer wherein the drive circuit is electrically connected with the exposed electrode of the electroluminescent chips through vias penetrating through the insulating layer.

In some embodiments, at attaching the electroluminescent chips to the transparent substrate, the method may further include forming a package layer for packaging the electroluminescent chips on the electroluminescent chips; grinding the package layer until electrodes of the electroluminescent chips are exposed; forming an insulating layer on the package layer; and forming a drive circuit on the insulating layer wherein the drive circuit is electrically connected with the exposed electrode of the electroluminescent chips through vias penetrating through the insulating layer.

In some embodiments, the method may further include forming a light uniformizing structure on a side of the transparent substrate away from the electroluminescent chips, wherein an orthographic projection area of the light uniformizing structure on the transparent substrate at least covers the electroluminescent chips.

Additional aspects and advantages of the present disclosure will be set forth in the following description, and it will become apparent from the following description or will be understood by the practice of the present disclosure.

### BRIEF DESCRIPTION OF THE DRAWINGS

The above and/or additional aspects and advantages of the present disclosure will become apparent and readily understood from the following description of the embodiments with reference to the accompanying drawings, in which:

FIG. 1 is a schematic structural diagram of a LED array as a light source;

FIG. 2 is a schematic structural diagram of an electroluminescent device according to an embodiment of the present disclosure;

FIG. 3 is a schematic structural diagram of an electroluminescent device as a light source according to an embodiment of the present disclosure;

FIG. 4 is a schematic structural diagram of another electroluminescent device according to an embodiment of the present disclosure;

FIGS. 5A, 6A, 7A, and 8A are schematic structural diagrams of electroluminescent devices when displaying according to embodiments of the present disclosure;

FIGS. 5B, 6B, 7B, and 8B are schematic structural diagrams of electroluminescent devices when being used as light sources according to embodiments of the present disclosure; and

FIGS. 9-11 are flow diagrams of methods of manufacturing an electroluminescent device according to embodiments of the present disclosure.

### DESCRIPTION OF EXAMPLE EMBODIMENTS

Hereinafter, embodiments of the present disclosure are described in detail with reference to the accompanying drawings, wherein the same or like reference numbers refer to the same or similar elements or elements having the same or similar functions throughout. The embodiments described in the following with reference to the accompanying drawings are exemplary and are used merely to explain the present disclosure and are not to be construed as limiting the present disclosure.

It should be apparent to those skilled in the art that the singular forms “a”, “an”, and “the” may further include plural forms unless specifically stated otherwise. It should further be understood that the ten “include”, “including”, “comprise” or “comprising” used in the specification of the present disclosure indicate existence of a feature, a number, a step, an operation, an element and/or a component, and do not exclude existence or addition of one or more other features, numerals, steps, operations, elements, components, or combinations thereof.

It should be understood that, when we refer to an element being “connected to” another element, it can be connected to the other element directly, or there may further be one or more intervening elements. Furthermore, the “connected to” used herein may include wireless connection. As used herein, the phrase “and/or” may include all or any unit and all combinations of one or more of the associated listed items.

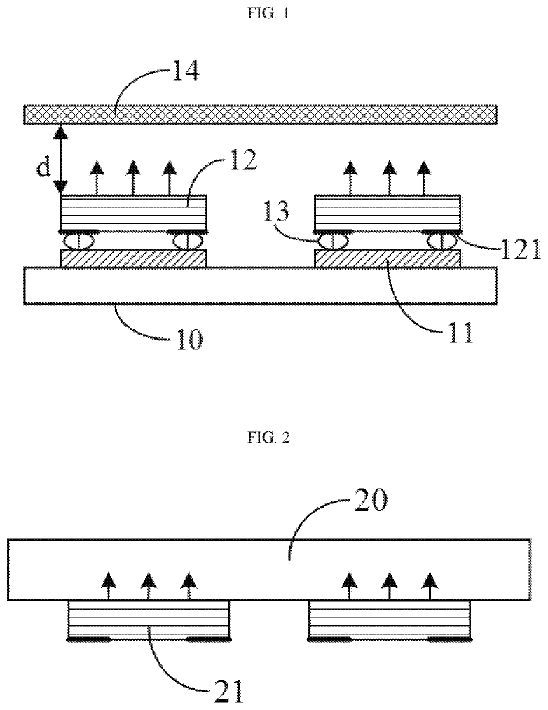

FIG. 1 is a schematic structural diagram of a LED array as a light source.

As shown in FIG. 1, a drive circuit 11 is formed on a substrate 10, which may be a transparent substrate or a non-transparent substrate, LED chips 12 may be electrically connected to the drive circuit 11 in a soldering manner, wherein the LED chips 12 may be a pin-down flip chip. Electrodes 121 of the LED chips 12 and connection points 13 of the drive circuit 11 may be electronically connected in a soldering or eutectic bonding manner.

As shown in FIG. 1, when the LED chips 12 are used as a backlight, it is necessary to place a light uniformizing plate 14 in light-emitting direction of the LED chips 12. The light uniformizing plate 14 may spread the light incident on the light uniformizing plate 14 in horizontal and vertical directions, such that light at a region where not directly illuminated by the LED chips 12 and at a region where illuminated several times by the LED chips 12 gets more evenly spread. The space between the light uniformizing plate 14 and the LED chips 12 may be an air layer, and the light uniformizing plate 14 may be supported by a frame (not shown in the drawing). In FIG. 1, d represents a light uniformizing distance required by the LED chips 12, and the direction of the arrow indicates the light-emitting direction of the LED chips 12.

While carrying out research on LED arrays as light source, inventors of the present disclosure have discovered that although LED arrays as a light source may be applied to general backlighting products, there are process difficulties and defeats for high-end products. Since there is a certain distance between a light uniformizing plate and LED chips, a light uniformizing distance between the light uniformizing plate and the LED chips in different regions may be changed when bent, so that the LED chips cannot be applied to flexible products. In addition, the LED chips are easily detached from a substrate as the LED chips and a drive circuit may be connected in a soldering or eutectic bonding manner, and the LED chips are relatively poor in service life and reliability. Due to the fact that an air layer is included between the LED chips and the light uniformizing plate, the light emitted by the LED chips has to first pass through the air layer to the light uniformizing plate and is then reflected by interfaces of air mediums twice, which causes greater light loss and low light efficiency.

The technical solutions of the present disclosure, as well as how the technical solutions of the present disclosure solve the above technical issues are described in detail below with specific embodiments. The following several specific embodiments may be combined with each other, and the same or similar concepts or processes may not be redundantly described in some embodiments,

The region size and thickness of each film or layer in the drawings do not represent the true region size and thickness of the film or layer and is merely for illustrative of specific embodiments of the present disclosure.

FIG. 2 is a schematic structural diagram of an electroluminescent device according to embodiments of the present disclosure.

As shown in FIG. 2, the electroluminescent device according to embodiments of the present disclosure may include a transparent substrate 20 and an array of electroluminescent chips 21 disposed on the transparent substrate 20. The light-emitting surfaces of the electroluminescent chips 21 are attached to the transparent substrate 20. The direction of the arrows in the drawing represents the light-emitting direction of the electroluminescent chips 21. Hereinafter, the electroluminescent chips 21 will be illustrated by taking LED chips as an example.

The transparent substrate 20 in embodiments of the present disclosure has a higher transmittance in the optically visible range. The transparent substrate 20 may be a flexible substrate or a rigid substrate such as a glass substrate.

According to the electroluminescent device of the present disclosure, since the light-emitting surfaces of the electroluminescent chips are attached to the transparent substrate, the electroluminescent chips are not easily detached from the transparent substrate, and the service life and reliability of the electroluminescent chips are improved. Besides, as the light-emitting surfaces of the electroluminescent chips are attached to the transparent substrate, and light emitted by the electroluminescent chips enters the transparent substrate, the interface reflection of the air medium is avoided, and the light efficiency can be improved. The light-emitting surfaces of the electroluminescent chips are attached to the transparent substrate, so that the light-emitting surfaces of the electroluminescent chips are at the same height, and the contact region of the attached electroluminescent chips and the transparent substrate is larger, so it is unlikely to cause the movement of the position of the electroluminescent chip on the transparent substrate, the uniformity of light emission of the electroluminescent chips can be improved, and the yield and reliability of the electroluminescent device can be improved.

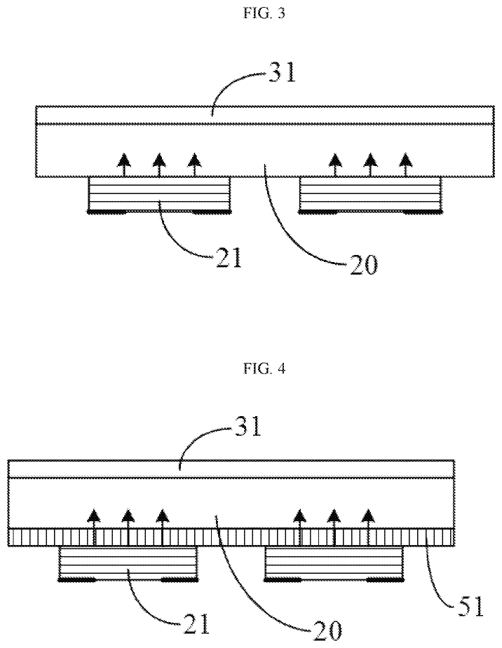

FIG. 3 is a schematic structural diagram of an electroluminescent device as a light source according to embodiments of the present disclosure.

As shown in FIG. 3, when the electroluminescent device is used as a light source, compared to the embodiment shown in FIG. 2, the electroluminescent device according to the present embodiment may further include a light uniformizing structure 31. The light uniformizing structure 31 is attached to one side of transparent substrate 20 away from the electroluminescent chips 21, and an orthographic projection region of the uniformizing structure 31 on the transparent substrate 20 at least covers the electroluminescent chips 21. In one embodiment, the light uniformizing structure 31 may cover the entire transparent substrate 20.

According to the embodiment, the light uniformizing structure 31 is attached to one side of the transparent substrate 20 away from the electroluminescent chips and when the transparent substrate 20 is a flexible transparent substrate, since a distance between the electroluminescent chips 21 and the light uniformizing structure 31 is a thickness of the transparent substrate 20, the distance between the electroluminescent chips 21 and the light uniformizing structure 31 in different regions is not changed when bent, so that a relatively uniform light may be provided for the flexible display product and may be used for flexible backlight.

In addition, since the light uniformizing structure 31 is attached to one side of the transparent substrate 20 away from the electroluminescent chips 21, a thickness of the product may be reduced compared to the prior art, and light emitted from the electroluminescent chips 21 does not need to pass through the air to enter the light uniformizing structure 31, the reflection of the air interfaces is reduced twice, and the light efficiency of the electroluminescent chips 21 is improved.

Specifically, when the electroluminescent device in the embodiment of the present disclosure is used as a light source, a thickness of the transparent substrate 20 of the embodiment of the present disclosure is equal to a light uniformizing distance required by the electroluminescent chip, and this type of arrangement may better provide uniform light. The light uniformizing distance required for the electroluminescent chips may be provided according to the light-emitting angle of the electroluminescent chips 21 and the spacing between adjacent electroluminescent chips 21, for example, the smaller the spacing between adjacent electroluminescent chips 21 is, the smaller the light uniformizing distance may be.

In some embodiments, the light uniformizing structure 31 may be a light uniformizing plate covering the entire transparent substrate 20, and in other embodiments, the light uniformizing structure 31 may be light diffusing layer covering the entire transparent substrate 20. The light diffusing layer may adjust the light-emitting angle of the electroluminescent chip to reduce the light scattering during dynamic dimming.

According to embodiments of the present disclosure, the light diffusing layer may be a scattering particle layer containing a base material, and may further be a microstructure layer. A thickness of the light diffusing layer is generally dozens of microns, and the microstructure layer may be a pillar having a size below the micron scale or various irregular patterns. Formation of the light diffusing layer may include, but is not limited to, coating a solution containing silicon dioxide (SiO₂) microparticles onto a surface of a transparent substrate, which after drying may produce a plurality of SiO₂ particles that can scatter the uniform light as a microstructure layer on the surface of the transparent substrate. The particles in the light diffusing layer may expand the illumination range of the electroluminescent chip to further reduce product thickness.

FIG. 4 is a schematic structural diagram of another electroluminescent device according to embodiments of the present disclosure.

As shown in FIG. 4. compared to the embodiment shown in FIG. 3, the electroluminescent device according to the present embodiment may further include a transmittance enhancement layer 51 between the transparent substrate 20 and the electroluminescent chips 21 for enhancing the transmittance of the light emitted from the electroluminescent chips 21. The light-emitting surfaces of the electroluminescent chips 21 are attached to the transmittance enhancement layer 51, and the transmittance enhancement layer 51 is attached to the transparent substrate 20. The transmittance enhancement layer 51 may be disposed only at positions corresponding to the electroluminescent chips 21 or may cover the entire transparent substrate 20.

According to embodiments of the present disclosure, the transmittance enhancement layer 51 may include an antireflection film layer with different refractive indexes or an antireflection film layer with graded indexes, alternatively, the transmittance enhancement layer 51 may include an antireflection film layer that matches the refractive index between a light-emitting substrate of the electroluminescent chips 21 and the transparent substrate 20.

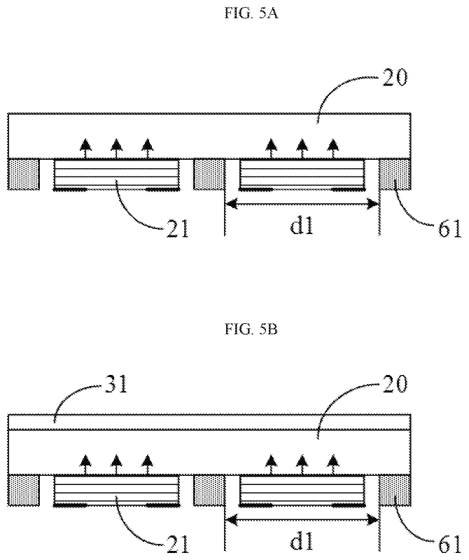

FIGS. 5A and 59 are schematic structural diagrams of an electroluminescent device when displaying and being used as a light source, respectively, according to embodiments of the present disclosure.

As shown in FIGS. 5A and 5B, compared to the embodiment shown in FIGS. 2 and 3, the electroluminescent device according to the present embodiment may further include a confinement layer 61. The confinement layer 61 is disposed on a side of the transparent substrate 20 to which the electroluminescent chips 21 are attached and surrounds the electroluminescent chips 21. The confinement layer 61 is used to confine positions of the electroluminescent chips 21.

A material of the confinement layer 61 may include an organic material. The material of the confinement layer 61 may include transparent material (e.g., transparent resin material) or non-transparent material (e.g., Epoxy Molding Compound (EMC)).

A thickness of the confinement layer 61 and a thickness of the electroluminescent chips 21 may be at the same scale. For example, with the same unit, the thickness of the confinement layer 61 is X×10^{y}, and the thickness of the electroluminescent chips 21 is A×10^{b}, where 1≤X<10, 1≤A<10, and y and b are positive integers or 0. If the thickness of the confinement layer 61 and the thickness of the electroluminescent chips 21 are at the same scale, y is equal to b, and X and A may or may not be equal.

The thickness of the confinement layer 61 and the thickness of the electroluminescent chips 21 at the same scale may better confine the positions of the electroluminescent chips 21, and protect the electroluminescent chips 21. In some embodiments, the thickness of the confinement layer 61 and the thickness of the electroluminescent chips 21 may be the same. In addition, as shown in FIGS. 5A and 5B, a size d1 of a confinement hole formed in the confinement layer 61 may be larger than a size of the electroluminescent chips 21 so that the manufacturing process is simplified. In other embodiments, the size d1 of the confinement hole may be the same as the size of the electroluminescent chips 21.

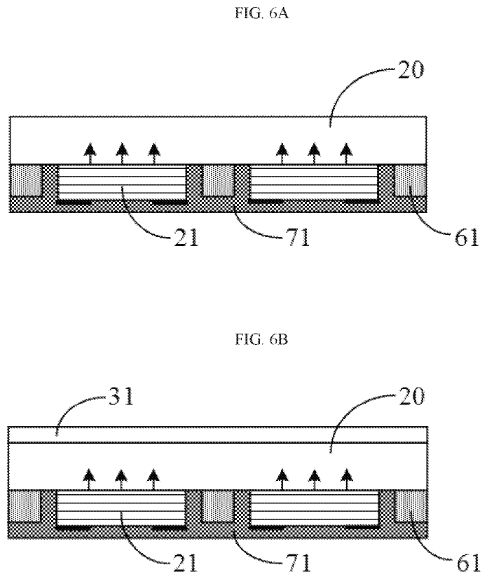

FIGS. 6A and 6B are schematic structural diagrams of an electroluminescent device when displaying and being used as a light source, respectively, according to embodiments of the present disclosure.

According to embodiments of the present disclosure, as shown in FIGS. 6A and 6B, a planarization layer 71 may further be formed on the electroluminescent device shown in FIGS. 5A and 5B. The planarization layer 71 may cover the electroluminescent chips 21 and the confinement layer 61, and may further fill the gaps between the electroluminescent chips 21 and the confinement layer 61 to protect the electroluminescent chips 21.

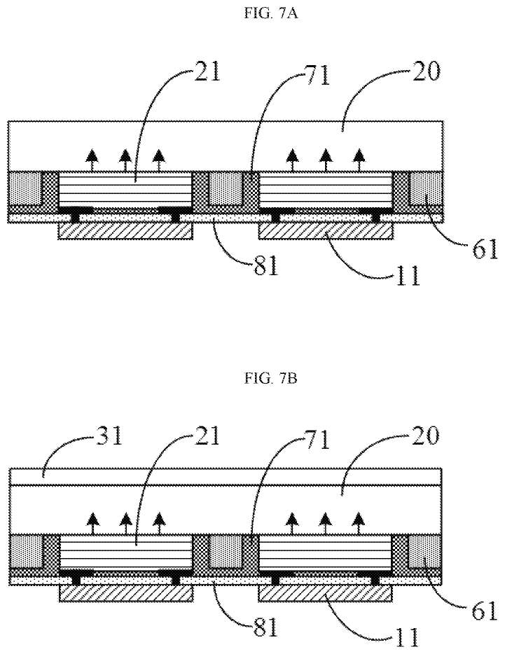

FIGS. 7A and 7B are schematic structural diagrams of an electroluminescent device when displaying and being used as a light source, respectively, according to embodiments of the present disclosure.

According to embodiments of the present disclosure, as shown in FIGS. 7A and 7B, an insulating layer 81 covering the planarization layer 71 and a drive circuit 11 on the insulating layer 81 may be formed on the electroluminescent device shown in FIGS. 6A and 6B. Vias in the insulating layer 81 may expose electrodes of the electroluminescent chips 21. Alternatively, the insulating layer may not be provided.

As shown in FIGS. 7A and 7B, the drive circuit 11 is electrically connected with the electrodes exposed by the electroluminescent chips 21 through the vias penetrating through the insulating layer 81.

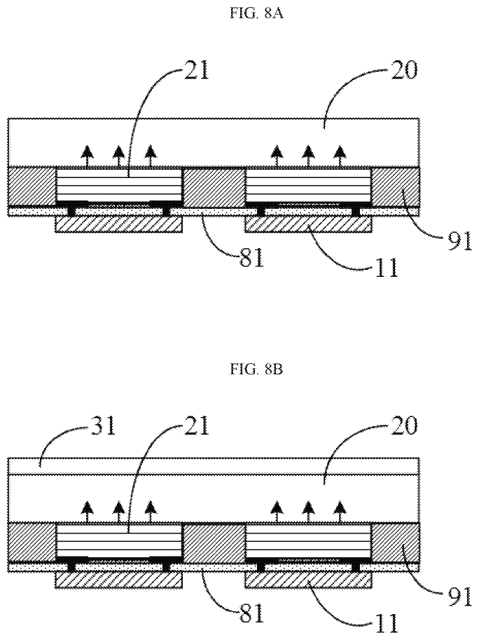

FIGS. 8A and 8B are schematic structural diagrams of an electroluminescent device when displaying and being used as a light source, respectively, according to embodiments of the present disclosure.

According to embodiments of the present disclosure, compared to the embodiment shown in FIGS. 7A and 7B, the electroluminescent device according to the present embodiment may include a package layer 91 covering the electroluminescent chips 21. In this case, the confinement layer and the planarization layer may not be provided, and the package layer 91 may function to locate the electroluminescent chips 21.

As shown in FIGS. 8A and 8B, the insulating layer 81 may cover the package layer 91, and the drive circuit 11 is provided on the insulating layer 81.

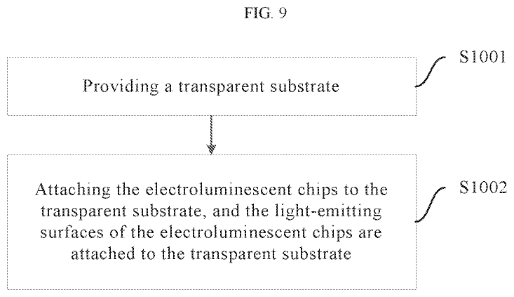

FIG. 9 is a flow diagram of a method of manufacturing an electroluminescent device according to an embodiment of the present disclosure.

As shown in FIG. 9, the method of manufacturing the electroluminescent device according to an embodiment of the present disclosure may include steps S1001 and S1002.

In step S1001, a transparent substrate is provided.

In step S1002, electroluminescent chips are attached to the transparent substrate, and the light-emitting surfaces of the electroluminescent chips are attached to the transparent substrate.

According to an embodiment of the present disclosure, step S1002 may include: forming transparent adhesive glue at the position where the electroluminescent chips need to be attached; and attaching the light-emitting surfaces of the electroluminescent chips to the adhesive glue.

The transparent adhesive may be formed by spraying, ink-jet printing and the like, and surface mount technology (SMT), die bonder, or pick and the place is then used to attach the light-emitting surfaces of the electroluminescent chips to the adhesive glue. The adhesive glue may enhance the bonding capacity of the electroluminescent chips and the transparent substrate, and may further block water and oxygen. After drying, the light-emitting surfaces of the electroluminescent chips may be in close contact with the transparent substrate.

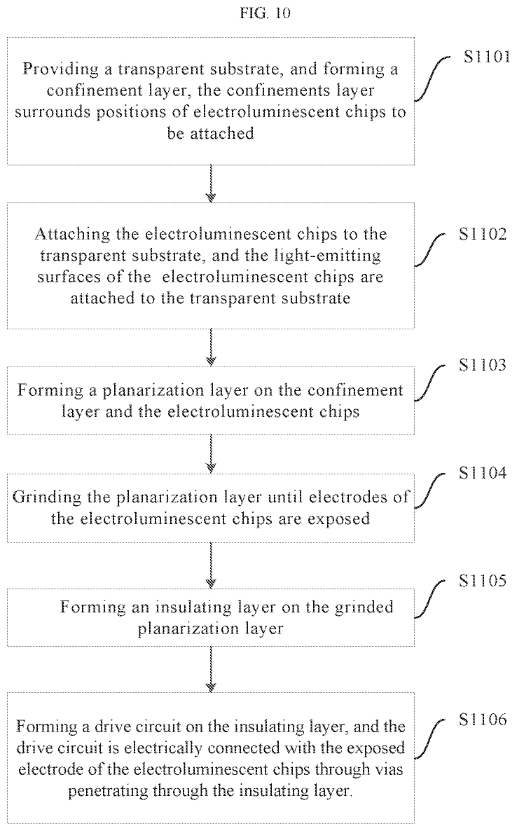

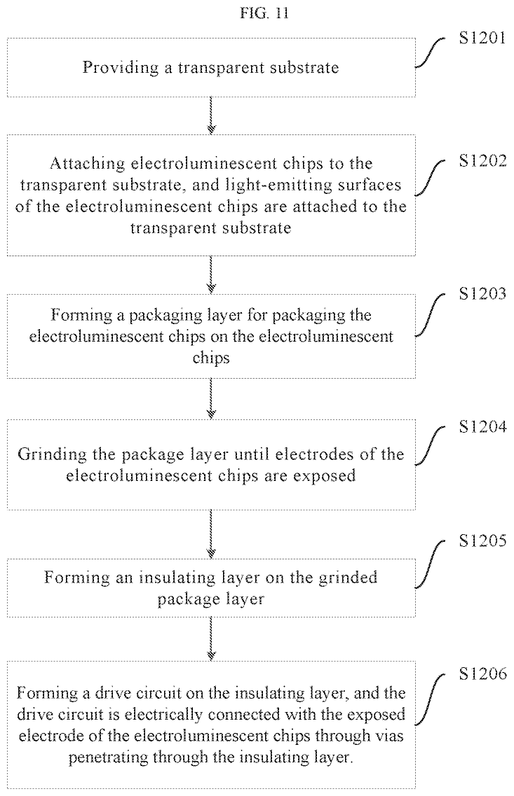

FIG. 10 is a flow diagram of another method of manufacturing the electroluminescent device according to an embodiment of the present disclosure.

As shown in FIG. 10, the method of manufacturing the electroluminescent device according to the embodiment of the present disclosure may include steps S1101 to S1106.

In step S1101, a transparent substrate is provided, and forming a confinement layer on the transparent substrate, wherein the confinement layer surrounds positions of electroluminescent chips to be attached.

In step S1102, the electroluminescent chips are attached to the transparent substrate, wherein the light-emitting surfaces of the electroluminescent chips are attached to the transparent substrate.

In step S1103, a planarization layer is formed on the confinement layer and the electroluminescent chips.

In step S1104, the planarization layer is grinded until electrodes of the electroluminescent chips are exposed.

In step S1105, an insulating layer is formed on the grinded planarization layer.

In step S1106, a drive circuit is formed on the insulating layer, and the drive circuit is electrically connected with the exposed electrodes of the electroluminescent chips through vias penetrating through the insulating layer.

In step 1101, when the confinement layer is formed on the transparent substrate, the confinement layer may be formed by a patterning process. The patterning process may include some or all of process of coating, exposing, developing, etching of a photoresist, in addition, the confinement layer shown in FIGS. 5A and 5B may be formed.

Step S1102 may include: forming transparent adhesive glue at the positions of the electroluminescent chips to be attached, and attaching the light-emitting surfaces of the electroluminescent chips to the adhesive glue.

In step S1103, when the planarization layer is formed on the confinement layer, the planarization layer may be formed by adopting a solution method, an ink-jet printing method or an ink-jet method, in addition, the planarization layer shown in FIGS. 6A and 6B may be formed.

In step S1104, the formed planarization layer may be grinded to expose the electrodes of the electroluminescent chips.

In step S1105, an insulating layer may be formed by methods of deposition, coating, or the like.

In step S1106, the drive circuit may be formed and connected in a conventional manner, for example, the electrodes of the electroluminescent chips and the drive circuit may be connected by solder or eutectic bonding, when the size of the electroluminescent chip is above 200 μm, a soldering approach may be adopted; when the size of the electroluminescent chip is below 100 μm, a eutectic bonding approach may be employed.

FIG. 11 is a flow diagram of another method of manufacturing the electroluminescent device according to an embodiment of the present disclosure.

As shown in FIG. 11, the method of manufacturing the electroluminescent device according to the embodiment of the present disclosure may include steps S1201 to S1206.

In step S1201, a transparent substrate is provided.

In step S1202, electroluminescent chips are attached to the transparent substrate, and light-emitting surfaces of the electroluminescent chips are attached to the transparent substrate.

In step S1203, a package layer for packaging the electroluminescent chips is formed on the electroluminescent chips.

In step S1204, the package layer is grinded until electrodes of the electroluminescent chips are exposed.

In step S1205, an insulating layer is formed on the package layer.

In step S1206, a drive circuit is formed on the insulating layer, and the drive circuit is electrically connected with the exposed electrodes of the electroluminescent chips through vias penetrating through the insulating layer.

In step S1203, when the package layer is formed on the electroluminescent chips, the package layer may be formed by coating approach, and the package layer material may be resin, also, the package layer shown in FIGS. 8A and 8B may be formed.

When an electroluminescent device according to an embodiment of the present disclosure is employed as a light source, a light uniformizing structure can be formed on one side of the transparent substrate away from the electroluminescent chip, and an orthographic projection of the light uniformizing structure on the transparent substrate at least covers the electroluminescent chips, for example, the light uniformizing structure shown in FIGS. 7B and 8B can be formed.

According to embodiments of the present disclosure, as the light-emitting surfaces of the electroluminescent chips are attached to the transparent substrate, the electroluminescent chips are not likely to detach from the transparent substrate, and the service life and the reliability of the electroluminescent chip are improved. The light-emitting surfaces of the electroluminescent chips are attached to the transparent substrate so that it is unlikely to cause positional movement of the electroluminescent chips on the transparent substrate, and luminescence uniformity of the electroluminescent chips may be improved, and then yield and reliability of the electroluminescent device may be improved.

When the light uniformizing structure is attached to the side of the transparent substrate away from the electroluminescent chips, since the distance between the electroluminescent chips and the light uniformizing structure is the thickness of the transparent substrate, the distance between the electroluminescent chips and the light uniformizing structure in different regions will not caused to be changed when the transparent substrate is bent, and therefore a relatively uniform light may be provided for the flexible display product.

The planarization layer and the package layer may perform integrally packaging for the electroluminescent chips, and since the light-emitting surfaces of the electroluminescent chips are attached to the transparent substrate, luminous efficiency of the electroluminescent chips can be greatly improved, and the life of the electroluminescent chips is prolonged.

The confinement layer can accurately locate the positions of the electroluminescent chips, reduce the influence of soldering flow on the positions of the electroluminescent chips, and luminous uniformity of the electroluminescent chips are improved.

Above is only partial embodiments of the present disclosure, and it should be noted that numerous modifications and variations can be made by those of ordinary skill in the art without departing from the principles of the disclosure, such modifications and variations are intended to be included within the scope of the present disclosure.

What is claimed is:

1. An electroluminescent device, comprising:
a transparent substrate and array of electroluminescent chips located on the transparent substrate,
wherein light-emitting surfaces of the electroluminescent chips are attached to the transparent substrate.

2. The electroluminescent device of claim 1, further comprising a light uniformizing structure attached to a side of the transparent substrate away from the electroluminescent chips, wherein an orthographic projection area of the light uniformizing structure on the transparent substrate at least covers the electroluminescent chips.

3. The electroluminescent device of claim 2, wherein a thickness of the transparent substrate is equal to a light uniformizing distance required by the electroluminescent chips.

4. The electroluminescent device of claim 1, further comprising a transmittance enhancement layer between the transparent substrate and the electroluminescent chips, and
the light-emitting surfaces of the electroluminescent chips are attached to the transmittance enhancement layer, and the transmittance enhancement layer is attached to the transparent substrate.

5. The electroluminescent device of claim 2, further comprising a transmittance enhancement layer between the transparent substrate and the electroluminescent chips, and
the light-emitting surfaces of the electroluminescent chips are attached to the transmittance enhancement layer which is attached to the transparent substrate.

6. The electroluminescent device of claim 1, further comprising a confinement layer on a side of the transparent substrate which the electroluminescent chips are attached to, and surrounding the electroluminescent chips.

7. The electroluminescent device of claim 2, further comprising a confinement layer on a side of the transparent substrate which the electroluminescent chips are attached to, and surrounding the electroluminescent chips.

8. The electroluminescent device of claim 6, wherein a material of the confinement layer comprises an organic material, and a thickness of the confinement layer and a thickness of the electroluminescent chips are at the same scale.

9. The electroluminescent device of claim 7, wherein a material of the confinement layer comprises an organic material, and a thickness of the confinement layer and a thickness of the electroluminescent chips are at the same scale.

10. The electroluminescent device of claim 6, further comprising:
a planarization layer covering the confinement layer and the electroluminescent chips;
an insulating layer covering the planarization layer; and
a drive circuit on the insulating layer,
wherein the planarization layer exposes electrodes of the electroluminescent chips, and the drive circuit is electrically connected with the exposed electrodes of the electroluminescent chips through vias penetrating through the insulating layer.

11. The electroluminescent device of claim 7, further comprising:
a planarization layer covering the confinement layer and the electroluminescent chips;
an insulating layer covering the planarization layer; and
a drive circuit on the insulating layer,
wherein the planarization layer exposes the electrodes of the electroluminescent chips, and the drive circuit is electrically connected with the exposed electrodes of the electroluminescent chips through vias penetrating through the insulating layer.

12. The electroluminescent device of claim 1, further comprising:
a package layer covering the electroluminescent chips;
an insulating layer covering the package layer; and
a drive circuit on the insulating layer,
wherein the package layer exposes electrodes of the electroluminescent chips, and the drive circuit is electrically connected with the exposed electrodes of the electroluminescent chips through vias penetrating through the insulating layer.

13. The electroluminescent device of claim 2, further comprising:
a package layer covering the electroluminescent chips;
an insulating layer covering the package layer; and
a drive circuit on the insulating layer,
wherein the package layer exposes the electrodes of the electroluminescent chips, and the drive circuit is electrically connected with the exposed electrodes of the electroluminescent chips through vias penetrating through the insulating layer.

14. A method of manufacturing an electroluminescent device, comprising:
providing a transparent substrate; and
attaching electroluminescent chips to the transparent substrate, wherein light-emitting surfaces of the electroluminescent chips are attached to the transparent substrate.

15. The method of claim 14, wherein before attaching the electroluminescent chips to the transparent substrate, the method further comprises:
forming a confinement layer on the transparent substrate wherein the confinement layer surrounds positions of the electroluminescent chips to be attached, and
after attaching the electroluminescent chips to the transparent substrate, the method further comprises:
forming a planarization layer on the confinement layer and the electroluminescent chips;
grinding the planarization layer until electrodes of the electroluminescent chips are exposed;
forming an insulating layer on the grinded planarization layer; and
forming a drive circuit on the insulating layer wherein the drive circuit is electrically connected with the exposed electrode of the electroluminescent chips through vias penetrating through the insulating layer.

16. The method of claim 14, wherein after attaching the electroluminescent chips to the transparent substrate, the method further comprises:
forming a package layer for packaging the electroluminescent chips on the electroluminescent chips;
grinding the package layer until electrodes of the electroluminescent chips are exposed;
forming an insulating layer on the package layer; and
forming a drive circuit on the insulating layer wherein the drive circuit is electrically connected with the exposed electrodes of the electroluminescent chips through vias penetrating through the insulating layer.

17. The method of claim 14, further comprising:
forming a light uniformizing structure on a side of the transparent substrate away from the electroluminescent chips, wherein an orthographic projection area of the light uniformizing structure on the transparent substrate at least covers the electroluminescent chips.

18. The method of claim 15, further comprising:
forming a light uniformizing structure on a side of the transparent substrate away from the electroluminescent chips, wherein an orthographic projection area of the light uniformizing structure on the transparent substrate at least covers the electroluminescent chips.

19. The method of claim 16, further comprising:
forming a light uniformizing structure on a side of the transparent substrate away from the electroluminescent chips, wherein an orthographic projection area of the light uniformizing structure on the transparent substrate at least covers the electroluminescent chips.
